(19) United States
(12) Patent Application Publication
(10) Pub. No.: US 2018/0337316 A1
(43) Pub. Date: Nov. 22, 2018

(54) JOINT STRUCTURE AND MANUFACTURING METHOD THEREOF

(71) Applicant: PANASONIC INTELLECTUAL PROPERTY MANAGEMENT CO., LTD., Osaka (JP)

(72) Inventors: Ikko KUZUHARA, Osaka (JP); Masashi KICHIMA, Niigata (JP)

(73) Assignee: PANASONIC INTELLECTUAL PROPERTY MANAGEMENT CO., LT D., Osaka (JP)

(21) Appl. No.: 15/983,517

(22) Filed: May 18, 2018

(30) Foreign Application Priority Data
May 22, 2017 (JP) 2017-100786

(51) Int. Cl. H01L 33/64; B32B 15/01; B32B 15/20; B32B 5/16; B22F 1/00; B22F 7/04

(52) U.S. Cl. CPC H01L 33/642; H01L 33/641; B32B 15/018; B32B 15/20; B32B 5/16; B22F 1/0018; B22F 2007/047; B22F 7/04; H01L 2933/0075; B32B 2457/00; B22F 2301/10; B22F 2301/255; B22F 1/0062

(57) ABSTRACT

A joint structure and a manufacturing method thereof are provided which can improve heat dissipation properties and which can inhibit damages. A joint structure includes: an insulating substrate and a heat dissipation substrate; a first silver particle layer that is joined to the insulating substrate and that includes a plurality of first silver nanoparticles which are joined; a second silver particle layer that is joined to the heat dissipation substrate and that includes a plurality of second silver nanoparticles which are joined; and a copper particle layer that interposes the first silver particle layer and the second silver particle layer, that is joined to the first silver particle layer and the second silver particle layer, and that includes a plurality of copper nanoparticles which are joined. A particle size of the copper nanoparticles is larger than particle size of both the first silver nanoparticles and the second silver nanoparticles.

### INCORPORATION BY REFERENCE

The disclosure of Japanese Patent Application No. 2017-100786 filed on May 22, 2017, including the specification, claims, drawings, and abstract, is incorporated herein by reference in its entirety.

### TECHNICAL FIELD

The present disclosure relates to a joint structure and a manufacturing method thereof.

### BACKGROUND

In the related art, there is known a joint structure as described in Japanese Unexamined Patent Application Publication No. 2008-28352. This joint structure includes a heat generating assembly including a heat generating element, and a heat dissipation assembly including a graphite layer. The heat generating assembly is joined to the heat dissipation assembly with a soldering layer therebetween. The joint structure allows the heat generated in the heat generating element to escape to the graphite layer through the soldering layer, to consequently realize suppression of erroneous operations of electronic components and a longer lifetime of a product.

Recently, highly dense integration of the heat generating element is being developed in connection with size reduction and improved performance of electronic devices. In order to realize highly dense integration of the heat generating element, there is a desire for improvement of the heat dissipation capability for the heat from the heat generating element.

Against such a background, when a nanoparticle joint layer, which is formed by joining many metal nanoparticles of the same species, is used in place of the soldering layer, the heat dissipation capability can be improved. However, because the nanoparticle joint layer is harder and consequently weaker against a stress as compared to the soldering layer, the joint structure tends to be more easily damaged when the nanoparticle joint layer is employed.

An advantage of the present disclosure lies in provision of a joint structure which can improve the heat dissipation capability and which can suppress damages, and a manufacturing method of the joint structure.

### SUMMARY

According to one aspect of the present disclosure, there is provided a joint structure including: a first joint member and a second joint member; a first metal particle layer that is joined to the first joint member, and that includes a plurality of first metal nanoparticles which are joined; a second metal particle layer that is joined to the second joint member, and that includes a plurality of second metal nanoparticles which are joined; and a third metal particle layer that interposes between the first metal particle layer and the second metal particle layer, that is joined to the first metal particle layer and the second metal particle layer, and that includes a plurality of third metal nanoparticles which are joined, wherein a particle size of the third metal nanoparticles is larger than particle sizes of both the first metal nanoparticles and the second metal nanoparticles.

According to another aspect of the present disclosure, there is provided a method of manufacturing a joint structure, including: a first nano-paste formation step in which a plurality of first metal nanoparticles are covered with an organic protective film, and are then dispersed in a solvent, to form a first metal nano-paste; a second nano-paste formation step in which a plurality of second metal nanoparticles are covered with an organic protective film, and are then dispersed in a solvent, to form a second metal nano-paste; a third nano-paste formation step in which a plurality of third metal nanoparticles having a larger particle size than particle sizes of both the first metal nanoparticles and the second metal nanoparticles are covered with an organic protective film, and are then dispersed in a solvent, to form a third metal nano-paste; and a joining step in which the organic protective films and the solvents of the first metal nano-paste, the second metal nano-paste, and the third metal nano-paste are decomposed and vaporized by baking, to join, in a layered state in this order, a first joint member, a first metal particle layer in which the plurality of the first metal nanoparticles are joined, a third metal particle layer in which the plurality of the third metal nanoparticles are joined, a second metal particle layer in which the plurality of the second metal nanoparticles are joined, and a second joint member.

In the present description, nanoparticles are defined to be particles having a particle diameter of less than or equal to 100 nm.

### ADVANTAGEOUS EFFECTS OF INVENTION

According to the present disclosure, in a joint structure, heat dissipation capability can be improved and damages can be suppressed.

### BRIEF DESCRIPTION OF DRAWINGS

The figures depict one or more implementations in accordance with the present teachings, by way of example only, not by way of limitations. In the figures, like reference numerals refer to the same or similar elements.

FIG. 1 is a schematic diagram of a joint structure according to a first embodiment of the present disclosure, as viewed from a side.

FIG. 2 is a schematic diagram of a joint structure according to a second embodiment of the present disclosure, as viewed from a side.

### DETAILED DESCRIPTION

Embodiments of the present disclosure will now be described in detail with reference to the attached drawings. In the following, when a plurality of embodiments and alternative configurations are included, suitable combination of the characteristic features thereof to construct a new embodiment is conceived of from the beginning.

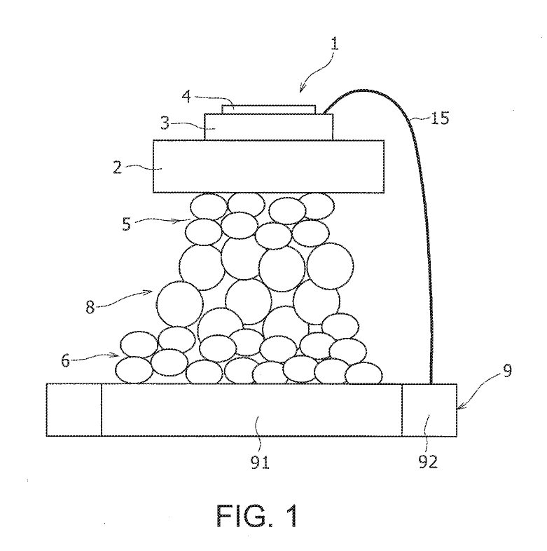

FIG. 1 is a schematic diagram of a joint structure 1 according to a first embodiment of the present disclosure, as viewed from a side. As shown in FIG. 1, the joint structure 1 comprises an insulating substrate 2 which is an example of a first joint member, a light emitting diode chip (“LED chip”) 3 mounted over the insulating substrate 2, a fluorescent member 4 placed on a front side of the LED chip 3, a first silver particle layer 5 which is an example of a first metal particle layer, a second silver particle layer 6 which is an example of a second metal particle layer, a copper particle layer 8 which is an example of a third metal particle layer, and a heat dissipation substrate 9 which is an example of a second joint member.

The insulating substrate 2 is a base structure over which the LED chip 3 is to be equipped, and has a function as a sub mount. As the insulating substrate 2, an insulating substrate made of ceramics is desirably employed, in order to suppress stress and strain due to a difference in a thermal expansion coefficient. For example, an AlN (aluminum nitride) substrate or an SiC (silicon carbide) substrate having a thermal expansion coefficient which is similar to that of the substrate material of the LED chip 3 and having a superior heat conductance is desirably employed.

The LED chip 3 is joined over the insulating substrate 2, for example, with a soldering layer therebetween. As the soldering layer, for example, solder of AuSn having Au as a primary material may be employed. In addition, oxides having a superior crystallinity and which emit light are mixed to a resin or the like, and are then applied on a light emission surface of the LED chip 3. In this manner, the fluorescent member 4 is formed on the light emission side of the LED chip 3.

The first silver particle layer 5 is joined on a side opposite from the side of equipment of the LED chip 3 on the insulating substrate 2. The first silver particle layer 5 includes a plurality of silver nanoparticles which are joined. The plurality of silver nanoparticles which are joined are an example of a plurality of first metal nanoparticles which are joined.

The second silver particle layer 6 is joined on a front surface of the heat dissipation substrate 9. More specifically, the heat dissipation substrate 9 includes a metal portion 91 formed from a metal, and a printed substrate 92 which is formed integral with the metal portion 91 and which is placed to surround the periphery of the metal portion 91. In other words, the heat dissipation substrate 9 is formed from the printed substrate 92 on a central part of which the metal portion 91 formed from a metal such as copper is embedded. The second silver particle layer 6 is joined to the metal portion 91 of the heat dissipation substrate 9. The second silver particle layer 6 includes a plurality of silver nanoparticles which are joined. The plurality of silver nanoparticles which are joined are an example of a plurality of second metal nanoparticles which are joined. Because the heat dissipation substrate 9 includes the printed substrate 92 having a lower heat endurance temperature than the insulating substrate 2, the heat dissipation substrate 9 has a lower heat endurance temperature than the insulating substrate 2.

The copper particle layer 8 is joined to the first silver particle layer 5 and the second silver particle layer 6, in a manner to interpose between the first silver particle layer 5 and the second silver particle layer 6. The copper particle layer 8 includes a plurality of copper nanoparticles which are joined. The plurality of copper nanoparticles which are joined are an example of a plurality of third metal nanoparticles which are joined. A particle size (diameter) of the copper nanoparticles included in the copper particle layer 8 is larger than a particle size of the silver nanoparticles included in the first silver particle layer 5, and also larger than a particle size of the silver nanoparticles included in the second silver particle layer 6. In addition, the LED chip 3 and an electric circuit (not shown) printed on the printed substrate 92 are electrically connected to each other by a wiring wire 15.

The joint structure 1 can be formed, for example, in the following manner. First, first, second, and third nano-past formation processes are executed. In the first nano-paste formation process, a plurality of the first silver nanoparticles are covered with an organic protective film, and are then dispersed in a solvent, to form a first silver nano-paste. In the second nano-paste formation process, a plurality of the second silver nanoparticles are covered with an organic protective film, and are then dispersed in a solvent, to form a second silver nano-paste. In the third nano-paste formation process, a plurality of the copper nanoparticles having a larger particle size than the first and second silver nanoparticles are prepared. Then, the plurality of copper nanoparticles are covered with an organic protective film, and are then dispersed in a solvent, to form a copper nano-paste. The first nano-paste is an example of a first metal nano-paste, and the second silver nano-paste is an example of a second metal nano-paste. The copper nano-paste is an example of a third metal nano-paste. The formations of the first through third nano-pastes may be executed in any order, and at least a part of formation times of two or more nano-pastes may overlap each other, or formations of the first through third nano-pastes may be executed simultaneously.

Next, a first baking process is executed. In the first baking process, after the first silver nano-paste and the copper nano-paste are sequentially placed (layered) over a back surface of the insulating substrate 2, the structure is baked for a first predetermined time at a first temperature. In this baking, the organic protective film and the solvent of the first metal nano-paste are decomposed and vaporized, and, at the same time, the organic protective film and the solvent of the third metal nano-paste are decomposed and vaporized. The first silver particle layer 5 in which the plurality of the first silver nanoparticles are joined and the copper particle layer 8 in which the plurality of the copper nanoparticles are joined are sequentially formed on the back surface of the insulating substrate 2, to form a combined structure in which the insulating substrate 2, the first silver particle layer 5, and the copper particle layer 8 are integrally joined.

After the first baking process, a second backing process is executed. In the second backing process, the second metal paste and the copper particle layer 8 included in the combined structure are sequentially placed (layered) over the metal portion 91 positioned at the central part of the heat dissipation substrate 9. Then, the structure is baked for a second predetermined time at a second temperature lower than the first temperature, to decompose and vaporize the organic protective film and the solvent of the second metal nano-paste. In this manner, the second silver particle layer 6 in which the plurality of the second silver nanoparticles are joined is formed over the metal portion 91, and is joined with the copper particle layer 8.

Then, the LED chip 3 is mounted on the front side of the insulating substrate 2 with a soldering layer (not shown) therebetween, and the fluorescent member 4 is formed on the front side of the LED chip 3. The LED chip 3 and the electric circuit of the printed substrate 92 are then electrically connected to each other by the wiring wire 15, and the joint structure 1 is formed.

The second metal paste formation process may be executed at any timing before the second baking process. In addition, the first baking process may be executed, for example, at a temperature in a range of 220˜320° C., and for any time in a range of 40˜80 minutes. The second baking process may be executed, for example, at a temperature in a range of 180˜210° C., and for any time in a range of 40˜80 minutes. However, the present embodiment is not limited to such a configuration, and other configurations may be employed, so long as the temperature at which the first baking process is executed is higher than the temperature at which the second baking process is executed.

In the joint structure 1 described above, the joint structure 1 comprises the insulating substrate 2 and the heat dissipation substrate 9, the first silver particle layer 5 which is joined to the insulating substrate 2 and which includes the plurality of the first silver nanoparticles which are joined, and the second silver particle layer which is joined to the heat dissipation substrate 9 and which includes the plurality of the second silver nanoparticles which are joined. In addition, the joint structure 1 includes the copper particle layer 8 which interposes between the first silver particle layer 5 and the second silver particle layer 6, which is joined to the first silver particle layer 5 and the second silver particle layer 6, and which includes the plurality of the copper nanoparticles which are joined. Moreover, the particle size of the copper nanoparticles is larger than the particle sizes of both the first silver nanoparticles and the second silver nanoparticles. In other words, the dense first silver particle layer 5 in which the first silver particles having a smaller particle size are placed in a closely existing manner is provided near the insulating substrate 2 on which the LED chip 3 which is a heat generating element is mounted. In addition, the dense second silver particle layer 6 in which the second silver particles having a smaller particle size is placed in a closely existing manner is provided near the metal portion 91 serving as a heat dissipation portion. Therefore, superior heat conduction can be realized from the insulating substrate 2 to the first silver particle layer 5 and also from the second silver particle layer 6 to the metal portion 91. In other words, superior heat conduction can be achieved near the heat generation side and near the heat dissipation side which significantly affects the heat dissipation capabilities, and thus, the heat dissipation capability can be improved in the joint structure 1.

In addition, copper particles having a larger particle size is provided between the dense first silver particle layer 5 having a smaller particle size and the dense second silver particle layer having a smaller particle size, and the copper particle layer 8 having a larger inter-particle distance than those of the first and second silver particle layers 5 and 6 is provided between the first and second silver particle layers 5 and 6. Therefore, the stress (strain) caused by a liner expansion can be absorbed and reduced by the lower-density, copper particle layer 8 in which the large-size particles are placed. Thus, the damages of the joint structure 1 can be suppressed.

Furthermore, while the heat dissipation substrate 9 in which a metal is embedded at a central part of the printed substrate 92 (for example, a copper inlay substrate or the like) is commercially available and can be inexpensively prepared, there also is a problem that because the heat endurance of the printed substrate 92 is low, the substrate cannot be baked at a temperature of about 250 degrees. On the other hand, when the metal particle layer is formed by jointing the plurality of metal nanoparticles through baking, the particles can be placed closer to each other as the baking temperature is increased, which results in superior heat conduction in the metal particle layer. Against such a background, in the first embodiment, the insulating substrate 2, the first silver particle layer 5, and the copper particle layer 8 are baked in the first baking process, and the heat dissipation substrate 9 including the printed substrate 92 having a lower heat endurance temperature is not baked in the first baking process. The heat dissipation substrate 9 including the printed substrate 92 is baked in the second baking process executed at a lower temperature and on the combined member obtained as a result of the first baking process, after the first baking process. Therefore, the baking temperature of the first baking process may be set high, superior heat conduction may be realized for the first silver particle layer 5 placed near the insulating substrate 2, and the heat dissipation substrate 9 including the inexpensive printed substrate 92 can be used.

The present disclosure is not limited to the above-described first embodiment and alternative configurations thereof, and various improvements and changes are possible within the items described in the claims and in an equivalent range thereof.

For example, in the above-described first embodiment, the LED chip 3 is formed on the side, of the insulating substrate 2, opposite from the side of the first silver particle layer 5, after the insulating substrate 2, the first silver particle layer 5, the copper particle layer 8, the second silver particle layer 6, and the heat dissipation substrate 9 are joined and combined. Alternatively, the LED chip may be provided over the insulating substrate before the first baking process is executed. Alternatively, the heat generating element may be different from the LED chip, and may be, for example, a CPU or an IC, or the like, or any other heat generating element.

In addition, a configuration is described in which the first metal particle layer is the first silver particle layer 5, the second metal particle layer is the second silver particle layer 6, and the third metal particle layer is the copper particle layer 8. Alternatively, each of the first through third metal particle layers may be a copper nanoparticle layer including a plurality of copper nanoparticles which are joined, a silver nanoparticle layer including a plurality of silver nanoparticles which are joined, or a gold nanoparticle layer including a plurality of gold nanoparticles which are joined. Alternatively, each of the first through third metal particle layers may be a nanoparticle layer including a plurality of rare metal nanoparticles which are joined.

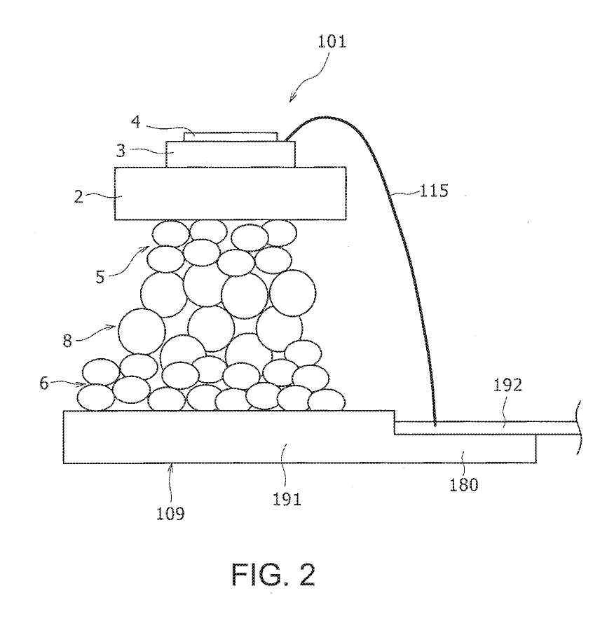

In addition, a configuration is described in which the heat dissipation substrate 9 has a structure in which a metal portion such as copper is embedded at the central part of the printed substrate 92. Alternatively, as in a second embodiment of the present disclosure to be described next with reference to FIG. 2, a heat dissipation substrate 109 may be formed by joining at a later time a printed substrate 192 to a metal substrate 191 made of a metal such as copper.

FIG. 2 is a schematic diagram corresponding to FIG. 1, showing a joint structure 101 according to the second embodiment of the present disclosure. In the second embodiment, the structures identical to those of the first embodiment are assigned the same reference numerals, and will not be described again. Further, operations, advantages, and alternative configurations similar to those of the first embodiment are also not described.

As shown in FIG. 2, in the joint structure 101 of the second embodiment, the heat dissipation substrate 109 includes the metal substrate 191 formed from copper or the like, and having a lightened portion (recess) 180 at a part on a front side. The printed substrate 192 is joined to the lightened portion 180 of the metal substrate 191 at a later time.

Specifically, in the second embodiment, similar to the first embodiment, after the first through third nano-paste formation processes are executed, the insulating substrate 2, the first silver nano-paste, the copper nano-paste, the second silver nano-paste, and the metal substrate 191 are layered in this order. Then, the structure is baked at once at a high temperature, to decompose and vaporize the organic protective film and the solvent from each of the first silver nano-paste, the copper nano-paste, and the second silver nano-paste by baking, and to join the layers to each other. In this manner, a structure is formed in which the insulating substrate 2, the first silver particle layer 5, the copper particle layer 8, the second silver particle layer 6, and the metal substrate 191 are integrally combined.

Then, the printed substrate 192 is joined to the front surface of the lightened portion 180 of the metal substrate 191 by a joint means such as, for example, an adhesive or welding. Then, similar to the first embodiment, the LED chip 3 and the fluorescent member 4 are formed on the front side of the insulating substrate 2, and the LED chip 3 and the electric circuit (not shown) printed on the printed substrate 192 are electrically connected to each other by a wiring wire 115, to form the joint structure 101. Here, the step of forming the LED chip 3 and the fluorescent member 4 at the front side of the insulating substrate 2 may be executed at any timing, similar to the first embodiment. In the second embodiment, the first joint member is formed from the insulating substrate 2, and the second joint member is formed from the metal substrate 191. In the second embodiment, a heat endurance temperature of the insulating substrate 2 may be higher than the heat endurance temperature of the metal substrate 191, or may be lower than or equal to the heat endurance temperature of the metal substrate 191.

According to the second embodiment, the organic protective films and the solvents of the first silver nano-paste, the second silver nano-paste, and the copper nano-paste are decomposed and vaporized by baking. The insulating substrate 2, the first silver particle layer 5 in which the plurality of the first silver nanoparticles are joined, the copper particle layer 8 in which the plurality of the copper nanoparticles are joined, the second silver particle layer 6 in which the plurality of the second silver nanoparticles are joined, and the metal substrate 191 are combined in a state of being layered in this order. The printed substrate 192 having a lower heat endurance is attached to the integrated, assembled structure (combined structure) after the insulting substrate 2, the first silver particle layer 5, the copper particle layer 8, the second silver particle layer 6, and the metal substrate 191 are integrally combined. Therefore, the assembled structure may be baked and combined regardless of the printed substrate 192 having the lower heat endurance. Therefore, the assembled structure including the first silver particle layer 5, the copper particle layer 8, and the second silver particle layer 6 can be formed by baking at a high temperature at once, and superior heat conductivity can be achieved between the layers of the assembled structure.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A joint structure comprising:
a first joint member and a second joint member;
a first metal particle layer that is joined to the first joint member, and that includes a plurality of first metal nanoparticles which are joined;
a second metal particle layer that is joined to the second joint member, and that includes a plurality of second metal nanoparticles which are joined; and
a third metal particle layer that interposes between the first metal particle layer and the second metal particle layer, that is joined to the first metal particle layer and the second metal particle layer, and that includes a plurality of third metal nanoparticles which are joined, wherein
a particle size of the third metal nanoparticles is larger than particle sizes of both the first metal nanoparticles and the second metal nanoparticles.

2. The joint structure according to claim 1, wherein
a heat endurance temperature of the first joint member is higher than a heat endurance temperature of the second joint member, and
the first metal particle layer is joined to the first joint member by baking, and the second metal particle layer is joined to the second joint member by baking.

3. The joint structure according to claim 2, wherein
the first joint member is an insulating substrate made of ceramics, and
the second joint member includes a metal portion formed form a metal, and a printed substrate which is formed integrally with the metal portion and which is placed to surround a periphery of the metal portion.

4. The joint structure according to claim 1, wherein
each of the first metal nanoparticles and the third metal nanoparticles is copper nanoparticles, silver nanoparticles, or gold nanoparticles.

5. The joint structure according to claim 1, wherein
the second metal nanoparticles are silver nanoparticles.

6. The joint structure according to claim 1, wherein
the first metal nanoparticles are silver nanoparticles, and the third metal nanoparticles are copper nanoparticles.

7. A method of manufacturing a joint structure, comprising:
covering a plurality of first metal nanoparticles with an organic protective film, and then dispersing the plurality of first metal nanoparticles in a solvent, to form a first metal nano-paste;
a covering plurality of second metal nanoparticles with an organic protective film, and then dispersing the plurality of second metal nanoparticles in a solvent, to form a second metal nano-paste;
covering a plurality of third metal nanoparticles having a larger particle size than particles sizes of both the first metal nanoparticles and the second metal nanoparticles with an organic protective film, and then dispersing the plurality of third metal nanoparticles in a solvent, to form a third metal nano-paste; and
decomposing and vaporizing by baking, the organic protective films and the solvents of the first metal nano-paste, the second metal nano-paste, and the third metal nano-paste, to join, in a layered state in this order, a first joint member, a first metal particle layer in which the plurality of the first metal nanoparticles are joined, a third metal particle layer in which the plurality of the third metal nanoparticles are joined, a second metal particle layer in which the plurality of the second metal nanoparticles are joined, and a second joint member.

8. The method of manufacturing the joint structure according to claim 7, wherein
the decomposing and vaporizing by baking comprises:
(A): sequentially placing the first metal nano-paste and the third metal nano-paste over the first joint member, and then, baking the resulting structure at a first temperature, to decompose and vaporize the organic protective film and the solvent of the first metal nano-paste and to decompose and vaporize the organic protective film and the solvent of the third metal nano-paste, to sequentially form, over the first joint member, the first metal particle layer in which the plurality of the first metal nanoparticles are joined and the third metal particle layer in which the plurality of the third metal nanoparticles are joined; and
(B): after performing (A), sequentially placing the second metal nano-paste and the third metal particle layer of a combined structure formed in (A) in this order over the second joint member having a lower heat endurance temperature than the first joint member, and then, the resulting structure is baked at a second temperature lower than the first temperature, to decompose and vaporize the organic protective film and the solvent of the second metal nano-paste, to thereby form, over the second joint member, the second metal particle layer in which the plurality of the second metal nanoparticles are joined, and join the second metal particle layer and the third metal particle layer.

9. The method of manufacturing the joint structure according to claim 8, wherein
the first joint member is an insulating substrate made of ceramics, and
the second joint member includes a metal portion formed from a metal, and a printed substrate which is formed integrally with the metal portion and which is placed to surround a periphery of the metal portion.

10. The method of manufacturing the joint structure according to claim 8, wherein
(A) is executed at a temperature in a range of 220° C.˜320° C. and for any time in a range of 40˜80 minutes, and (B) is executed at a temperature in a range of 180° C.˜210° C. and for any time in a range of 40˜80 minutes.

11. The method of manufacturing the joint structure according to claim 7, wherein
each of the first metal nanoparticles and the third metal nanoparticles is copper nanoparticles, silver nanoparticles, or gold nanoparticles.

12. The method of manufacturing the joint structure according to claim 7, wherein
the second metal nanoparticles are silver nanoparticles.

13. The method of manufacturing the joint structure according to claim 7, wherein
the first metal nanoparticles are silver nanoparticles, and the third metal nanoparticles are copper nanoparticles.
